(19) United States
(12) Patent Application Publication
(10) Pub. No.: US 2008/0254584 A1
(43) Pub. Date: Oct. 16, 2008

(54) METHOD OF MANUFACTURING FLASH MEMORY DEVICE

(76) Inventor: Jae-Young Choi, Yongin-si (KR)

Correspondence Address: SHERR & VAUGHN, PLLC, 620 HERNDON PARKWAY, SUITE 200, HERNDON, VA, 20170, US

(21) Appl. No.: 12/102,326

(22) Filed: Apr. 14, 2008

(30) Foreign Application Priority Data
Apr. 16, 2007 (KR) 10-2007-0036741

(51) Int. Cl. H01L 21/8247

(52) U.S. Cl. 438/258; 257/E21.691

(57) ABSTRACT

A method for manufacturing a flash memory device including providing a semiconductor substrate having a cell region and a periphery region; and then adjusting a threshold voltage of the cell region; and then forming a memory device on the cell region and forming a transistor on the periphery region; and then forming an interlayer dielectric layer on the memory device and the transistor, wherein the height of a first portion of the interlayer dielectric layer at the cell region is greater the height of a second portion of the interlayer dielectric layer at the periphery region; and then removing the height difference between the first portion of the interlayer dielectric layer and the second portion of the interlayer dielectric layer.

The present application claims priority under 35 U.S.C. 119 and 35 U.S.C. 365 to Korean Patent Application No. 10-2007-0036741 (filed on Apr. 16, 2007), which is hereby incorporated by reference in its entirety.

### BACKGROUND

A flash memory device is a nonvolatile memory that does not lose data stored therein even if power is turned off. Flash memory devices may provide a relatively high data processing speed when data is recorded, read, and deleted.

Accordingly, flash memory devices may be widely used for a Bios to store data in a personal computer (PC), a set-top box, a printer, and a network sever. Flash memory devices may also be extensively used in digital cameras, portable phones, etc.

Flash memory devices may include a cell region and a periphery region. The cell region may be provided for writing and deleting data. The cell region may include a floating gate and a control gate. The periphery region may be provided for operating a transistor corresponding to the data write operation and the delete operation. The periphery region may include a gate electrode.

Such flash memory devices, however, may include a step-difference between the cell region and the periphery region, causing difficulty in forming an interlayer dielectric layer on and/or over a substrate including the cell region and the periphery region. The step-difference may also cause difficulty in planarizing the interlayer dielectric layer during a chemical mechanical polishing (CMP) process.

### SUMMARY

Embodiments relate to a method for manufacturing a flash memory device capable of stably removing a step-difference formed between a cell region and a periphery region.

Embodiments relate to a method including at least one of the following steps: forming an isolation layer on a substrate having a cell region and a periphery region; and then forming a first photoresist pattern on the periphery region using a mask and then implanting ions into the cell region through the mask; and then forming a memory device on the cell region and forming a transistor on the periphery region; and then forming an interlayer dielectric layer on the substrate including the cell region and the periphery region, wherein the surface of the interlayer dielectric layer has a step difference between the cell region and the periphery region; and then forming a second photoresist pattern on the periphery region using the mask; and then performing an etching process with respect to the interlayer dielectric layer of the cell region.

Embodiments relate to a method including at least one of the following steps: providing a semiconductor substrate having a cell region and a periphery region; and then adjusting a threshold voltage of the cell region; and then forming a memory device on the cell region and forming a transistor on the periphery region; and then forming an interlayer dielectric layer on the memory device and the transistor, wherein the height of a first portion of the interlayer dielectric layer at the cell region is greater the height of a second portion of the interlayer dielectric layer at the periphery region; and then removing the height difference between the first portion of the interlayer dielectric layer and the second portion of the interlayer dielectric layer.

Embodiments relate to a method including at least one of the following steps: forming an isolation layer on a substrate having a cell region and a periphery region; and then adjusting a threshold voltage of the cell region by performing an ion implantation process on the semiconductor substrate using a mask; and then forming a first poly-silicon pattern and a second poly-silicon pattern on the cell region of the semiconductor substrate; and then forming a dielectric layer on the first poly-silicon pattern and the second poly-silicon pattern; and then forming a third poly-silicon pattern on the dielectric layer and a fourth poly-silicon pattern on the periphery region of the semiconductor substrate; and then forming an interlayer dielectric layer on the entire semiconductor substrate, wherein the surface of the interlayer dielectric layer has a step difference located between the cell region and the periphery region; and then removing the step difference by forming a second photoresist pattern on the interlayer dielectric layer using the mask and performing an etching process on a portion of the interlayer dielectric layer.

### DRAWINGS

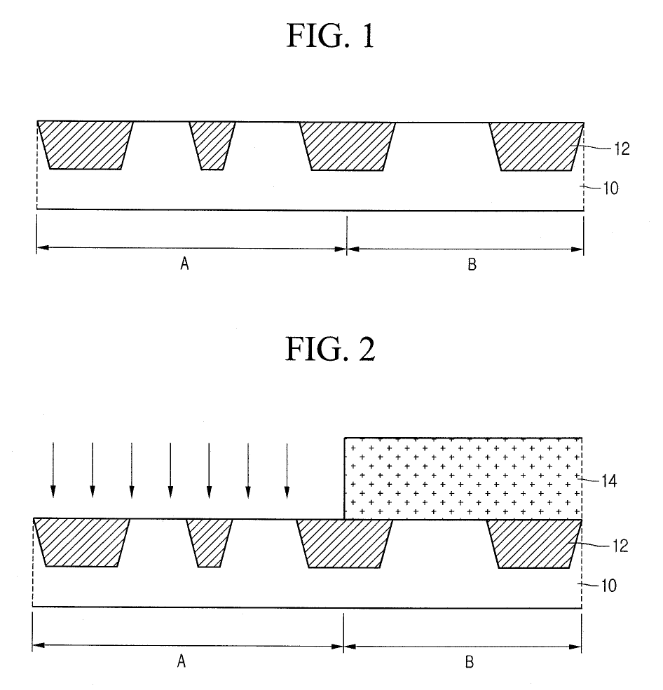

Example FIGS. 1 to 9 illustrate a method of fabricating a flash memory device, in accordance with embodiments.

### DESCRIPTION

As illustrated in example FIG. 1, semiconductor substrate 10 including cell region A and periphery region B may be patterned forming a trench. Insulating material, such as boro-phospho silicate glass (BPSG) or a silicon oxide layer, can then be filled in the trench. The resultant structure can then be subject to a chemical mechanical polishing (CMP) process to form isolation layer 12. Isolation layer 12 can serves as a region for insulating various devices from each other, such devices being formed later on and/or over semiconductor substrate 10. Prior to forming isolation layer 12, an oxide layer can be formed on and/or over semiconductor substrate 10. The oxide layer can be used as a gate oxide in a gate region.

A well can be formed in semiconductor substrate 10 including isolation layer 12. As illustrated in example FIG. 2, an ion implantation process can then be performed with respect to semiconductor substrate 10 to adjust a threshold voltage of cell region A. In the ion implantation process for adjusting the threshold voltage of cell region A, first photoresist pattern 14 can be formed on and/or over periphery region B using a mask and ions are exclusively implanted into cell region A. The mask can later be reused when planarizing an interlayer dielectric layer.

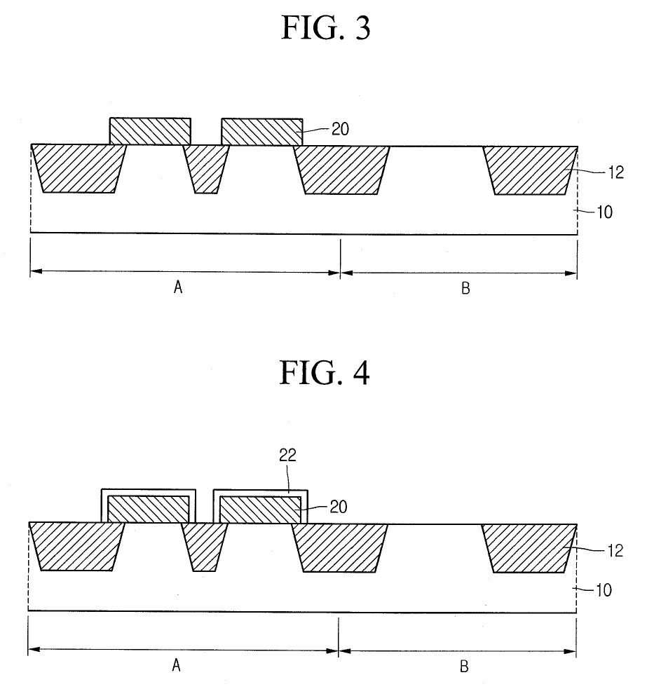

As illustrated in example FIG. 3, poly-silicon can then be formed on and/or over semiconductor substrate 10 including isolation layer 12. The resultant structure can then be patterned, thereby forming first poly-silicon pattern 20 on and/or over cell region A. First poly-silicon pattern 20 can serve as a floating gate.

As illustrated in example FIG. 4, a first oxide layer, a nitride layer and second oxide layer can then be sequentially formed on and/or over semiconductor substrate 10 including first poly-silicon pattern 20. The resultant structure can then be subject to an annealing process and a patterning process, to form Oxide-Nitride-Oxide (ONO) layer 22 on and/or over first poly-silicon pattern 20 of cell region A. Particularly, first poly-silicon pattern 20 can be surrounded by ONO layer 22. ONO layer 22 can serve to insulate the floating gate from a control gate.

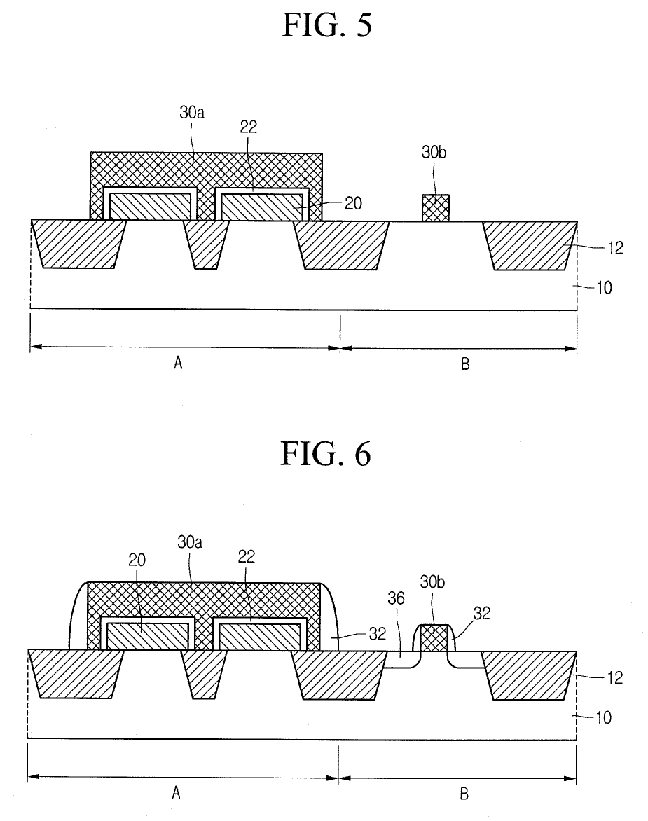

As illustrated in example FIG. 5, a second poly-silicon layer can then be formed on and/or over semiconductor substrate 10 including ONO layer 22. The poly-silicon layer can then be patterned to form second poly-silicon pattern 30a on and/or over cell region A and third poly-silicon pattern 30b formed on and/or over periphery region B.

Second poly-silicon pattern 30a formed on and/or over ONO layer 22 in cell region A can serve as a control gate. Second poly-silicon pattern 30a formed in cell region A can serve to apply bias voltage such that electrons existing in first poly-silicon pattern 20 positioned below second poly-silicon layer 30a are excited to perform at least one of a charging operation and a discharging operation. Third poly-silicon pattern 30b formed directly on and/or semiconductor substrate 10 in periphery region B can serve as a gate electrode.

As illustrated in example FIG. 6, a second ONO layer can then be formed on and/or over semiconductor substrate 10 including second poly-silicon pattern 30a and third poly-silicon pattern 30b. The second ONO layer can then be patterned to thereby form spacer 32 at both sides of second poly-silicon pattern 30a formed on and/or over cell region A and third poly-silicon pattern 30b formed on and/or over periphery region B. Although embodiments have described spacer 32 having a multi-layered ONO structure, spacer 32 may include other structures such as an ON (Oxide-Nitride) structure including an oxide layer and a nitride layer.

An ion implantation process can then be performed using spacer 32 and second poly-silicon pattern 30a and third poly-silicon pattern 30b as masks to thereby form source/drain area 36 on and/or over semiconductor substrate 10.

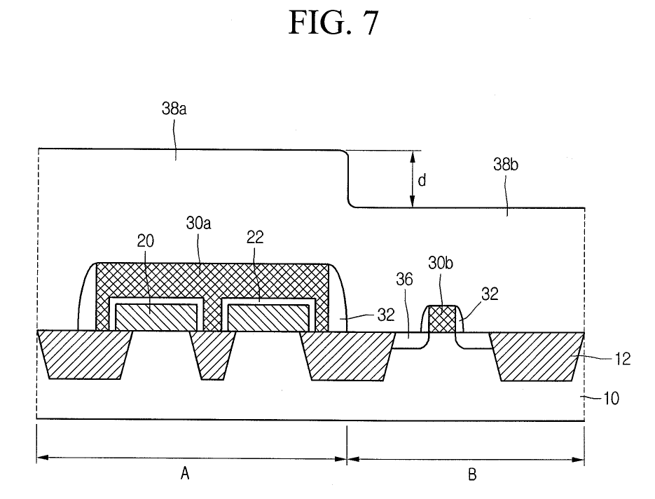

As illustrated in example FIG. 7, interlayer dielectric layer 38 including first interlayer dielectric layer portion 38a and second interlayer dielectric layer portion 38b can then be formed on and/or over the entire semiconductor substrate 10 including source/drain region 36. First interlayer dielectric layer portion 38a and second interlayer dielectric layer portion 38b can be composed of an insulating material such as one of undoped silicate glass (USG) and boro-phospho silicate glass (BPSG). Since second poly-silicon pattern 30a of cell region A is formed on and/or over ONO layer 22 and first poly-silicon pattern 20, second poly-silicon pattern 30a can have a thickness greater than that of third poly-silicon pattern 30b of periphery region B by a thickness of ONO layer 22 and first poly-silicon pattern 20.

Accordingly, when interlayer dielectric layer 38 is formed on and/or the semiconductor substrate 10, step difference “d” at the uppermost surface thereof results. Particularly, when first interlayer dielectric layer portion 38a is formed on and/or over second poly-silicon pattern 30a and second interlayer dielectric layer portion 38b is formed on and/or over third poly-silicon layer pattern 30b, step difference “d” is formed between cell region A and periphery region B. Meaning, since cell region A is formed with first poly-silicon pattern 20 and ONO layer 22, and periphery region B does not have such structures thereon, first interlayer dielectric layer portion 38a of cell region A has a greater height than that of second interlayer dielectric layer portion 38b of periphery region B. This height differential is substantially equal to the combined thickness of first poly-silicon pattern 20 and ONO layer 22.

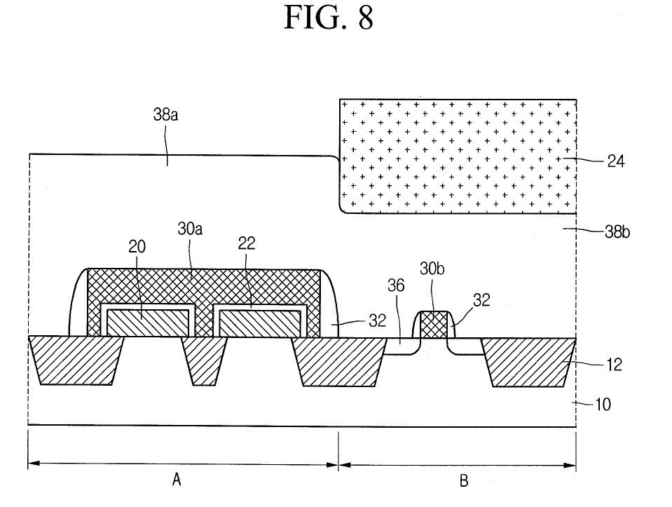

As illustrated in example FIG. 8, second photoresist pattern 24 can then be formed on and/or over second interlayer dielectric layer portion 38b of periphery region B. Second photoresist pattern 24 can be formed by reusing the mask previously used for adjusting the threshold voltage. Accordingly, first photoresist pattern 14 and second photoresist pattern 24 can be formed on and/or over the same region. Because the mask is reused, the process of forming the photoresist pattern is performed without an additional mask, thereby reducing overall manufacturing costs.

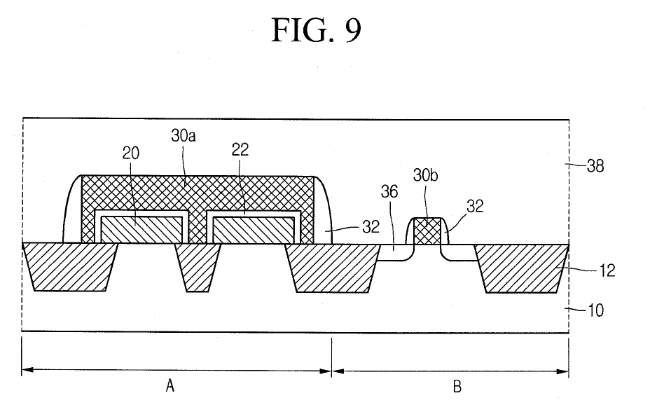

As illustrated in example FIG. 9, an etching process can then be performed with respect to first interlayer dielectric layer portion 38a of cell region A to reduce the thickness of first interlayer dielectric layer portion 38a to make it coplanar with second interlayer dielectric layer portion 38. In essence, first interlayer dielectric layer portion 38a can be etched in order that it may have a substantially identical height to that of second interlayer dielectric layer portion 38b of periphery region B. Consequently, step difference “d” formed between first interlayer dielectric layer 38a of cell region A and second interlayer dielectric layer portion 38b of periphery region B is removed. The etching process can be performed using reactive ion etching. In addition, a CMP process may be performed to obtain an improved uniformity between first interlayer dielectric layer portion 38a of cell region A and second interlayer dielectric layer portion 38b of periphery region B.

First interlayer dielectric layer portion 38a of cell region A and second interlayer dielectric layer portion 38b of periphery region B can then be selectively etched to form a via-hole, in which a contact plug is formed therein. Through the formation of the contact plug, second poly-silicon pattern 30a and third poly-silicon pattern 30b and source/drain region 36 can be electrically connected to each other.

In accordance with embodiments, a method of manufacturing a flash memory device can be performed by using a single mask, thereby reducing overall manufacturing costs. Moreover, a step difference between the interlayer dielectric layer can be stably removed, thereby preventing a contact failure and a defect such as a gate defect, which is caused when the interlayer dielectric layer is over-etched.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming an isolation layer on a substrate having a cell region and a periphery region; and then
forming a first photoresist pattern on the periphery region using a mask and then implanting ions into the cell region through the mask; and then
forming a memory device on the cell region and forming a transistor on the periphery region; and then
forming an interlayer dielectric layer on the substrate including the cell region and the periphery region, wherein the surface of the interlayer dielectric layer has a step difference located between the cell region and the periphery region; and then
forming a second photoresist pattern on the periphery region using the mask; and then
removing the step difference by performing an etching process with respect to the interlayer dielectric layer of the cell region.

2. The method as claimed in claim 1, further comprising a step of performing a chemical mechanical polishing process with respect to the interlayer dielectric layer formed on the cell region and the periphery region after performing the etching process.

3. The method of claim 1, further comprising, after removing the step difference:
forming a via-hole by patterning the interlayer dielectric layer; and then
forming a contact plug in the via-hole.

4. The method of claim 1, wherein the etching process comprises a reactive ion etching process.

5. The method of claim 1, wherein performing the etching process makes the surface of the interlayer dielectric layer at the cell region coplanar with the surface of the interlayer dielectric layer at the periphery region.

6. The method of claim 1, wherein the interlayer dielectric layer comprises at least one of undoped silicate glass and boro-phospho silicate glass.

7. The method of claim 1, wherein forming the memory device on the cell region and forming the transistor on the periphery region comprises:
forming a first poly-silicon pattern on the cell region; and then
forming a dielectric layer covering the first poly-silicon pattern; and then
forming a second poly-silicon pattern on the dielectric layer of the cell region and a third poly-silicon pattern directly on the substrate of the periphery region.

8. The method of claim 7, further comprising forming spacers on sidewalls of the second poly-silicon pattern and the third poly-silicon pattern.

9. The method of claim 8, wherein the dielectric layer and the spacer comprise an ONO layer.

10. The method of claim 7, wherein the second poly-silicon pattern has a greater thickness than the third poly-silicon pattern.

11. The method of claim 1, wherein the first photo-resist pattern and the second photo-resist pattern are formed on a same region of the substrate.

12. A method of forming as flash memory device comprising:
providing a semiconductor substrate having a cell region and a periphery region; and then
adjusting a threshold voltage of the cell region; and then
forming a memory device on the cell region and forming a transistor on the periphery region; and then
forming an interlayer dielectric layer on the memory device and the transistor, wherein the height of a first portion of the interlayer dielectric layer at the cell region is greater the height of a second portion of the interlayer dielectric layer at the periphery region; and then
removing the height difference between the first portion of the interlayer dielectric layer and the second portion of the interlayer dielectric layer.

13. The method of claim 12, wherein adjusting the threshold voltage comprises:
forming a first photoresist pattern on the periphery region using a mask; and then
performing an ion implantation process on the semiconductor substrate by implanting ions directly into the cell region.

14. The method of claim 13, wherein removing the height difference comprises:
forming a second photoresist pattern on the second portion of the interlayer dielectric layer using the mask; and then
performing an etching process with respect to the first portion of the interlayer dielectric layer.

15. The method of claim 12, wherein removing the height difference comprises:
forming a second photoresist pattern on the second portion of the interlayer dielectric layer; and then
performing an etching process with respect to the first portion of the interlayer dielectric layer.

16. The method of claim 12, wherein forming the memory device and forming the transistor comprises:
forming a first poly-silicon pattern and a second poly-silicon pattern on the cell region of the semiconductor substrate; and then
forming a dielectric layer on the first poly-silicon pattern and the second poly-silicon pattern; and then
forming a third poly-silicon pattern on the dielectric layer and a fourth poly-silicon pattern on the periphery region of the semiconductor substrate; and then
forming spacers on sidewalls of the third poly-silicon pattern and the fourth poly-silicon pattern.

17. A method of forming as flash memory device comprising:
forming an isolation layer on a substrate having a cell region and a periphery region; and then
adjusting a threshold voltage of the cell region by performing an ion implantation process on the semiconductor substrate using a mask; and then
forming a first poly-silicon pattern and a second poly-silicon pattern on the cell region of the semiconductor substrate; and then
forming a dielectric layer on the first poly-silicon pattern and the second poly-silicon pattern; and then
forming a third poly-silicon pattern on the dielectric layer and a fourth poly-silicon pattern on the periphery region of the semiconductor substrate; and then
forming an interlayer dielectric layer on the entire semiconductor substrate, wherein the surface of the interlayer dielectric layer has a step difference located between the cell region and the periphery region; and then
removing the step difference by forming a second photoresist pattern on the interlayer dielectric layer using the mask and performing an etching process on the interlayer dielectric layer.

18. The method of claim 17, wherein the third poly-silicon pattern has a greater thickness than the fourth poly-silicon pattern.

19. The method of claim 17, further comprising, after performing the etching process:
performing a chemical mechanical polishing process on the interlayer dielectric layer; and then;
forming a via-hole by patterning the interlayer dielectric layer; and then
forming a contact plug in the via-hole.

20. The method of claim 17, further comprising, after forming the third poly-silicon pattern and the fourth poly-silicon pattern:
forming spacers on sidewalls of the third poly-silicon pattern and the fourth poly-silicon pattern.
